(19) United States
(12) Patent Application Publication
(10) Pub. No.: US 2026/0188252 A1
(43) Pub. Date: Jul. 2, 2026

(54) GATE DRIVING CIRCUIT AND DISPLAY DEVICE INCLUDING SAME

(71) Applicant: LG Display Co., Ltd., Seoul (KR)

(72) Inventors: Yeon Gyeong BAE, Paju-si (KR); Jun Ho BONG, Paju-si (KR); Min Woo PARK, Paju-si (KR)

(73) Assignee: LG Display Co., Ltd., Seoul (KR)

(21) Appl. No.: 19/392,673

(22) Filed: Nov. 18, 2025

(30) Foreign Application Priority Data
Dec. 31, 2024 (KR) 10-2024-0202640

(51) Int. Cl. G09G 3/3266

(52) U.S. Cl. CPC G09G 3/3266; G09G 2310/0286; G09G 2330/021

(57) ABSTRACT

A display device includes a display panel and a gate driver having an emission control signal generator, wherein the emission control signal generator includes a first output transistor turned on based on a first voltage to output an emission control signal at a turn-on voltage, a second output transistor turned on based on a second voltage to output an emission control signal at a turn-off voltage, a (1-1)th control transistor turned on based on a third voltage to control the first voltage to be charged at a first node, a (1-2)th control transistor turned on based on a fourth voltage to control the second voltage to be charged at the first node, and a node control transistor turned on based on at least one clock signal to transmit a signal for forming the third voltage or the fourth voltage to the second node.

### CROSS-REFERENCE TO RELATED APPLICATION(S)

This application claims the benefit of Korean Patent Application No. 10-2024-0202640, filed on Dec. 31, 2024, which is hereby incorporated by reference as if fully set forth herein.

### TECHNICAL FIELD

The present disclosure relates to an apparatus and particularly to, for example, without limitation, a gate driving circuit and a display device including the same.

### DESCRIPTION OF THE RELATED ART

As information technology develops, the market for display devices serving as connecting media between users and information, is growing. Accordingly, the use of display devices such as light emitting display (LED) devices, quantum dot display (QDD) devices, and liquid crystal display (LCD) devices is increasing.

The display devices described above include a display panel including subpixels, a driver that outputs a driving signal to drive the display panel, and a power supply that generates power to be supplied to the display panel or the driver.

The display devices described above can display images by allowing selected subpixels to transmit light or directly emit light when driving signals, such as a scan signal and a data signal, are supplied to the subpixels formed on the display panel.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### BRIEF SUMMARY

The present disclosure is directed to a gate driving circuit and a display device including the same, which, among others, substantially obviate one or more problems due to limitations and disadvantages of the related art.

Embodiments of the present disclosure reduce power consumption by configuring an emission control signal driver based on CMOS transistors and implementing a transistor that controls output using an oxide thin film transistor to secure a turn-on condition (Turn on Vgs) in which a high peak-to-peak voltage Vpp as in the case of bootstrap is not generated.

Embodiments of the present disclosure reduce or improve a problem caused by toggling delay by driving transistors based on a gate low voltage divided into different levels in the emission control signal driver.

Embodiments of the present disclosure provide a gate driver including an emission control signal driver capable of securing operational reliability, operational stability, and a threshold voltage margin.

Embodiments of the present disclosure reduce the area occupied by the gate driver and facilitate margin management by eliminating some oxide thin film transistors when implementing the emission control signal driver.

Additional improvements, characteristics, and features of the present disclosure will be set forth in part in the description which follows and in part will become apparent to those having ordinary skill in the art upon examination of the following or may be learned from practice of the present disclosure. The features and other technical improvements of the present disclosure may be realized and attained by the structure particularly pointed out in the written description and claims hereof as well as the appended drawings.

As embodied and broadly described herein, a display device includes a display panel configured to display an image, and a gate driver having an emission control signal generator configured to supply an emission control signal to the display panel, wherein the emission control signal generator includes a first output transistor turned on based on a first voltage charged at a first node to output an emission control signal at a turn-on voltage, a second output transistor turned on based on a second voltage charged at the first node and different from the first voltage to output an emission control signal at a turn-off voltage, a (1-1)th control transistor turned on based on a third voltage charged at a second node to control the first voltage to be charged at the first node, a (1-2)th control transistor turned on based on a fourth voltage charged at the second node and different from the third voltage to control the second voltage to be charged at the first node, and a node control transistor turned on based on at least one clock signal to transmit a signal for forming the third voltage or the fourth voltage to the second node.

The clock signal may be generated based on a gate high voltage corresponding to the turn-off voltage and a second gate low voltage lower than a gate low voltage corresponding to the turn-on voltage and toggled between a high voltage and a low voltage.

The first output transistor and the second output transistor may be configured as CMOS transistors.

The first output transistor may have a gate electrode connected to the first node, a first electrode connected to a gate low voltage line, and a second electrode connected to an output terminal, and the second output transistor has a gate electrode connected to the first node, a first electrode connected to a gate high voltage line, and a second electrode connected to the output terminal.

The node control transistor may include a transistor having a gate electrode connected to a first clock signal line through which a first clock signal is transmitted, a first electrode connected to a start signal line or an output terminal of an (N−1)th stage (N being an integer equal to or greater than 1), and a second electrode connected to the second node.

The node control transistor may include a (2-1)th control transistor having a gate electrode connected to a second clock signal line through which a second clock signal is transmitted, a first electrode connected to a start signal line or an output terminal of an (N−1)th stage (N being an integer equal to or greater than 1), and a second electrode connected to the second node, and a (2-2)th control transistor having a gate electrode connected to a first clock signal line through which a first clock signal is transmitted, a first electrode connected to the start signal line or the output terminal of the (N−1)th stage, and a second electrode connected to the second node.

The second clock signal may have a low voltage based on a second gate low voltage lower than a gate low voltage corresponding to a low voltage of the first clock signal.

In another aspect of the present disclosure, a display device includes a display panel configured to display an image, and a gate driver having a scan signal generator configured to supply a scan signal to the display panel, and an emission control signal generator configured to supply an emission control signal to the display panel, wherein the emission control signal generator includes a first output transistor turned on based on a first voltage charged at a first node to output an emission control signal at a turn-on voltage, a second output transistor turned on based on a second voltage charged at the first node and different from the first voltage to output an emission control signal at a turn-off voltage, a (1-1)th control transistor turned on based on a third voltage charged at a second node to control the first voltage to be charged at the first node, a (1-2)th control transistor turned on based on a fourth voltage charged at the second node and different from the third voltage to control the second voltage to be charged at the first node, and a node control transistor configured to transmit a signal for forming the third voltage or the fourth voltage to the second node.

The first output transistor may have a gate electrode connected to the first node, a first electrode connected to a gate low voltage line, and a second electrode connected to an output terminal, and the second output transistor may have a gate electrode connected to the first node, a first electrode connected to a gate high voltage line, and a second electrode connected to the output terminal.

The node control transistor may include a transistor having a gate electrode connected to a first clock signal line through which a first clock signal is transmitted, a first electrode connected to a start signal line or an output terminal of an (N−1)th stage (N being an integer equal to or greater than 1), and a second electrode connected to the second node.

The node control transistor may include a (2-1)th control transistor having a gate electrode connected to a second clock signal line through which a second clock signal is transmitted, a first electrode connected to a start signal line or an output terminal of an (N−1)th stage (N being an integer equal to or greater than 1), and a second electrode connected to the second node, and a (2-2)th control transistor having a gate electrode connected to a first clock signal line through which a first clock signal is transmitted, a first electrode connected to the start signal line or the output terminal of the (N−1)th stage, and a second electrode connected to the second node.

The emission control signal generator may be disposed symmetrically in a non-active area on one side of the display panel and a non-active area on the other side of the display panel.

The scan signal generator may include a first scan signal generator disposed in the non-active area on one side of the display panel, and a second scan signal generator disposed in the non-active area on the other side of the display panel.

In another aspect of the present disclosure, a gate driving circuit has an emission control signal generator including a first output transistor turned on based on a first voltage charged at a first node to output an emission control signal at a turn-on voltage, a second output transistor turned on based on a second voltage charged at the first node and different from the first voltage to output an emission control signal at a turn-off voltage, a (1-1)th control transistor turned on based on a third voltage charged at a second node to control the first voltage to be charged at the first node, a (1-2)th control transistor turned on based on a fourth voltage charged at the second node and different from the third voltage to control the second voltage to be charged at the first node, and a node control transistor turned on based on at least one clock signal to transmit a signal for forming the third voltage or the fourth voltage to the second node.

The clock signal may be generated based on a gate high voltage corresponding to the turn-off voltage and a second gate low voltage lower than a gate low voltage corresponding to the turn-on voltage and toggled between a high voltage and a low voltage.

The node control transistor may include a transistor having a gate electrode connected to a first clock signal line through which a first clock signal is transmitted, a first electrode connected to a start signal line or an output terminal of an (N−1)th stage (N being an integer equal to or greater than 1), and a second electrode connected to the second node.

The node control transistor may include a (2-1)th control transistor having a gate electrode connected to a second clock signal line through which a second clock signal is transmitted, a first electrode connected to a start signal line or an output terminal of an (N−1)th stage (N being an integer equal to or greater than 1), and a second electrode connected to the second node, and a (2-2)th control transistor having a gate electrode connected to a first clock signal line through which a first clock signal is transmitted, a first electrode connected to the start signal line or the output terminal of the (N−1)th stage, and a second electrode connected to the second node.

The second clock signal may have a low voltage based on a second gate low voltage lower than a gate low voltage corresponding to a low voltage of the first clock signal.

It is to be understood that both the foregoing general description and the following detailed description of the present disclosure are examples and explanatory and are intended to provide further explanation of the present disclosure as claimed.

It is to be understood that both the foregoing general description and the following detailed description are examples and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a block diagram schematically showing a display device;

FIG. 2 is a block diagram showing a configuration of a gate driver in the display device;

FIG. 3 is a circuit configuration diagram of a subpixel included in a display panel, and

FIG. 4 shows driving waveforms of the subpixel shown in FIG. 3;

FIG. 5 is a cross-sectional view of a display panel implemented based on the subpixel shown in FIG. 3;

FIG. 6 is a circuit configuration diagram of an emission control signal driver according to a first embodiment,

FIG. 7 shows driving waveforms of the emission control signal driver shown in FIG. 6, and

FIG. 8 to FIG. 11 show operation states of the emission control signal driver according to the driving waveforms of FIG. 7; and

FIG. 12 is a circuit configuration diagram of an emission control signal driver according to a second embodiment,

FIG. 13 shows driving waveforms of the emission control signal driver shown in FIG. 12, and

FIG. 14 to FIG. 17 show operation states of the emission control signal driver according to the driving waveforms of FIG. 13.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

In the following description, when a detailed description of well-known functions or configurations related to this document is determined to unnecessarily cloud a gist of the inventive concept, the detailed description thereof will be omitted or may be briefly discussed.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure.

A shape, a size, a ratio, an angle, and a number disclosed in the drawings for describing embodiments of the present disclosure may be merely an example. Thus, the present disclosure is not limited to the illustrated details. Like reference numerals refer to like elements throughout. In the following description, when the detailed description of the relevant known function or configuration is determined to unnecessarily obscure an important point of the present disclosure, the detailed description of such known function or configuration may be omitted. When “comprise,” “have,” and “include” described in the present specification are used, another part may be added unless “only” is used. An element described in a singular form is intended to include a plurality of elements, and vice versa, unless the contrary context clearly indicates otherwise.

Any implementation described herein as an “example” is not necessarily to be construed as preferred or advantageous over other implementations.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

In the description of the various embodiments of the present disclosure, where positional relationships are described, for example, when a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

In describing elements of the present disclosure, the terms “first,” “second,” “A,” “B,” “(a),” and “(b),” etc., may be used. These terms may be merely for differentiating one element from another element, and the essence, sequence, order, or number of a corresponding element should not be limited by the terms. For example, a first element could be termed a second element, and, similarly, a second element could be termed a first element, without departing from the scope of the present disclosure.

Also, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

A display device according to the present disclosure may be implemented as a light emitting display (LED) device, a quantum dot display (QDD) device, a liquid crystal display (LCD) device, or the like. However, for convenience of description, a light emitting display device that directly emits light based on inorganic light-emitting diodes or organic light-emitting diodes is used as an example of the display device.

In addition, a light-emitting display device which will be described below may be implemented in the form of an n-type thin film transistor, a p-type thin film transistor, or a form in which both n-type and p-type thin film transistors exist together. A thin film transistor is a three-electrode element including a gate, a source, and a drain. The source is an electrode that supplies carriers to the transistor. In the thin film transistor, carriers start to flow from the source. The drain is an electrode through which carriers leave the thin film transistor. In other words, carriers flow from the source to the drain in the thin film transistor.

In the case of a p-type thin film transistor, holes serve as carriers, and thus a source voltage is higher than a drain voltage such that the holes can flow from the source to the drain. Since the holes flow from the source to the drain in the p-type thin film transistor, the current flows from the source to the drain. In contrast, in the case of an n-type thin film transistor, electrons serve as carriers, and thus the source voltage is lower than the drain voltage such that the electrons can flow from the source to the drain. Since the electrons flow from the source to the drain in the n-type thin film transistor, the current flows from the drain to the source. However, the source and drain of a thin film transistor can be changed depending on the applied voltage. To reflect this, in the following description, one of the source and drain is described as a first electrode, and the other of the source and drain is described as a second electrode.

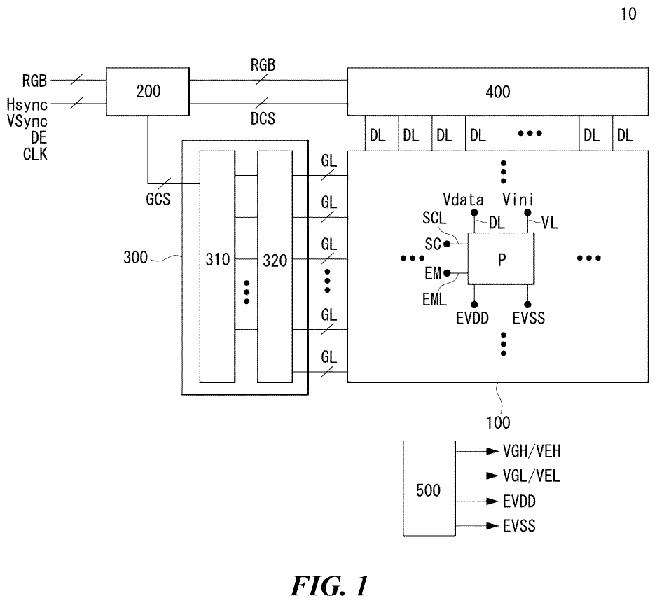

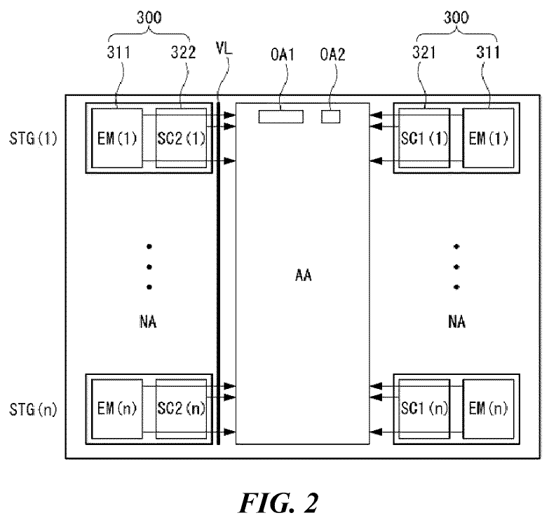

FIG. 1 is a block diagram schematically showing a display device. FIG. 2 is a block diagram showing a configuration of a gate driver in the display device.

As shown in FIG. 1, the display device 10 may include a display panel 100 including a plurality of subpixels P, a controller 200, a gate driver (gate driving circuit) 300 that supplies gate signals to the plurality of subpixels P, a data driver (data driving circuit) 400 that supplies data signals (or data voltages) to the plurality of subpixels P, and a power supply 500 that supplies power to the plurality of subpixels P.

The display panel 100 may include an active area (refer to AA in FIG. 2) in which the subpixels P are positioned, and a non-active area (refer to NA in FIG. 2) which is positioned to surround the active area AA and in which the gate driver 300 and the data driver 400 are disposed.

In the display panel 100, a plurality of gate lines GL and a plurality of data lines DL intersect each other, and the plurality of subpixels P may be connected to the gate lines GL and the data lines DL. Specifically, one subpixel P may receive a gate signal from the gate driver 300 through the gate line GL, receive a data voltage (data signal) from the data driver 400 through the data line DL, and receive a high-level voltage EVDD and a low-level voltage EVSS from the power supply 500.

The gate lines GL may transmit a scan signal SC and an emission control signal EM to the plurality of subpixels P, and the data lines DL may transmit a data voltage Vdata to the plurality of subpixels P. According to various embodiments, the gate lines GL may include a plurality of scan lines SCL for supplying the scan signal SC and a plurality of emission control lines EML for supplying the emission control signal EM. The plurality of subpixels P may receive a voltage Vini from a voltage line VL. A plurality of voltage lines VL may be positioned between the gate driver 300 and the active area AA.

Each of the plurality of subpixels P may include a subpixel driving circuit. The subpixel driving circuit may include a plurality of switching elements, driving elements, capacitors, etc. The switching elements and driving elements, etc., may be configured as thin film transistors. A switching transistor may be switched according to a scan signal SC supplied through a scan line SCL and an emission control signal EM supplied through an emission control line EML. A driving transistor may control the amount of current supplied to a light-emitting element OLED according to a data voltage Vdata (control the amount of emission).

The display panel 100 may be implemented as a non-transmissive display panel or a transmissive display panel. The transmissive display panel may be applied to a transparent display device in which an image is displayed on a screen and an actual object in the background is visible. The display panel 100 may also be implemented as a flexible display panel. The flexible display panel may use a plastic substrate. Each of the plurality of subpixels P may be divided into a red subpixel, a green subpixel, and a blue subpixel for color expression. Each of the plurality of subpixels P may further include a white subpixel.

Touch sensors may be disposed on the display panel 100. Touch input may be sensed using separate touch sensors or through the plurality of subpixels P. The touch sensors may be implemented as on-cell type or add-on type touch sensors disposed on the screen of the display panel or as in-cell type touch sensors built into the display panel 100.

The controller 200 may process an image data signal RGB input from the outside to suit to the size and resolution of the display panel 100 and supply the same to the data driver 400. The controller 200 may generate a gate control signal GCS and a data control signal DCS using external synchronous signals, for example, a dot clock signal CLK, a data enable signal DE, a horizontal synchronization signal Hsync, and a vertical synchronization signal Vsync. The controller 200 may control the operation timing of the gate driver 300 by supplying the gate control signal GCS to the gate driver 300. The controller 200 may control the operation timing of the data driver 400 by supplying the data control signal DCS to the data driver 400. The controller 200 may synchronize the operation timing of the gate driver 300 with the operation timing of the data driver 400 using the gate control signal GCS and the data control signal DCS.

The controller 200 may be configured to be combined with various processors, such as a microprocessor, a mobile processor, and an application processor depending on the device mounted thereon. A host system located in front of the controller 200 may be any one of a television (TV) system, a set-top box, a navigation system, a personal computer (PC), a home theater system, a mobile device, a wearable device, or a vehicle system.

The controller 200 may control the operation timing of a display panel driver at a frame frequency of input frame frequency×i Hz (i being a positive integer greater than 0) by multiplying the input frame frequency by i. The input frame frequency may be 60 Hz in the NTSC (National Television Standards Committee) system and 50 Hz in the PAL (Phase Alternating Line) system. However, the present disclosure is not limited thereto.

The controller 200 may drive the display panel 100 at various refresh rates. The controller 200 may drive the display panel 100 in a variable refresh rate (VRR) mode, that is, in such a manner that the display panel 100 can be switched between a first refresh rate and a second refresh rate.

For example, the controller 200 may drive the display panel 100 at various refresh rates by simply changing the rate of a clock signal, configuring a synchronization signal such that a horizontal blank or a vertical blank is generated, or driving the gate driver 300 in a mask manner. The vertical blank can be defined as a period for matching the timing of input of a data signal and the timing of output (display) of an image on the display panel. The vertical blank can be repeated in one frame cycle, and various signals for the operation of the display device can be synchronized during the period.

The voltage level of the gate control signal GCS output from the controller 200 may be converted into gate on voltages VGL and VEL and gate off voltages VGH and VEH through a level shifter (not shown) and supplied to the gate driver 300. The level shifter may convert a low level voltage of the gate control signal GCS into a gate low voltage VGL and may convert a high level voltage of the gate control signal GCS into a gate high voltage VGH. The gate control signal GCS may include a start pulse signal and a shift clock signal.

The gate driver 300 may supply gate signals to the gate lines GL according to the gate control signal GCS supplied from the controller 200. The gate driver 300 may be disposed on one side or both sides of the display panel 100 in a gate-in-panel (GIP) structure.

The gate driver 300 may sequentially output gate signals to the plurality of gate lines GL under the control of the controller 200. The gate driver 300 may sequentially supply the gate signals to the gate lines GL by shifting the gate signals using a shift register.

The gate signals may include a scan signal SC and an emission control signal EM in an organic light-emitting display device. The scan signal SC may include a scan pulse that swings between the gate low voltage VGL and a gate high voltage VGH. The emission control signal EM may include an emission control signal pulse that swings between a gate on voltage VEL and a gate off voltage VEH. The scan pulse can select subpixels P of a line to which a data voltage Vdata will be written. The emission control signal EM can define an emission time of the subpixels P.

The gate driver 300 may include an emission control signal driver 310 and at least one scan driver 320. The emission control signal driver 310 may output an emission control signal pulse in response to a start pulse and a shift clock from the controller 200 and sequentially shift the emission control signal pulse according to the shift clock. The at least one scan driver 320 may output a scan pulse in response to a start pulse and a shift clock from the controller 200 and shift the scan pulse according to shift clock timing.

The data driver 400 may convert image data RGB into a data voltage Vdata according to a data control signal DCS supplied from the controller 200, and output the data voltage Vdata through a data line DL.

Although FIG. 1 illustrates that one data driver 400 is disposed one side of the display panel 100, the number and positions of data drivers 400 are not limited thereto. That is, the data driver 400 may be composed of a plurality of integrated circuits (ICs) which are disposed on one side of the display panel 100.

The power supply 500 may generate DC power required to drive the subpixel array of the display panel 100 and the display panel driver using a DC-DC converter. The DC-DC converter may include a charge pump, a regulator, a buck converter, a boost converter, etc. The power supply 500 may receive a DC input voltage applied from the host system that is not shown and generate DC voltages such as the gate on voltages VGL and VEL, the gate off voltages VGH and VEH, the high-level voltage EVDD, and the low-level voltage EVSS. The gate on voltages VGL and VEL and the gate off voltages VGH and VEH may be supplied to a level shifter (not shown) and the gate driver 300. The high-level voltage EVDD and the low-level voltage EVSS may be supplied commonly to the plurality of subpixels P.

As shown in FIG. 1 and FIG. 2, the gate driver 300 may include an emission control signal driver 311 and scan drivers 321 and 322. Shift registers constituting the gate driver 300 may be configured to be symmetrical on both sides of the active area AA.

Stages STG1 to STGn of the shift registers may include first scan signal generators SC1(SC1(1) to SC1(n), second scan signal generators SC2(1) to SC2(n), and emission control signal generators EM1(1) to EM1(n).

The first scan signal generators SC1(1) to SC1(n) may output first scan signals through first scan lines of the display panel 100. The second scan signal generators SC2(1) to SC2(n) may output second scan signals through second scan lines of the display panel 100. The emission control signal generators EM1(1) to EM1(n) may output emission control signals through emission control lines of the display panel 100.

The first scan signal generators SC1(1) to SC1(n) and the second scan signal generators SC2(1) to SC2(n) may be disposed on both sides of the display area AA. The first scan signal generators SC1(1) to SC1(n) and the second scan signal generators SC2(1) to SC2(n) may be connected to scan lines such that one scan signal can be applied to one scan line. The emission control signal generators EM1(1) to EM1(n) may be disposed (symmetrically disposed) on both sides of the active area AA. The emission control signal generators EM1(1) to EM1(n) may be commonly connected to two emission control lines such that an emission control signal common to two scan lines can be applied.

The first scan signals may be used as signals for driving an A transistor (e.g., a compensation transistor, etc.) included in the subpixel driving circuit. The second scan signals may be used as signals for driving a B transistor (e.g., a data supply transistor, etc.) included in the subpixel driving circuit. The emission control signals may be used as signals for driving a C transistor (e.g., an emission control transistor, etc.) included in the subpixel driving circuit.

Further, a personal computer, a mobile device, a wearable device, and the like may include one or more optical areas OA1 and OA2 disposed in the active area AA. The optical areas OA1 and OA2 may be disposed to overlap one or more optoelectronic devices, such as imaging devices such as a camera (image sensor) and detection sensors such as a proximity sensor and an illuminance sensor.

The optical areas OA1 and OA2 may have a light-transmitting structure formed for the operation of the optoelectronic devices, and thus may have a transmittance of a certain level or higher. In other words, the number of pixels P per unit area in the optical areas OA1 and OA2 may be smaller than the number of pixels P per unit area in the general area other than the optical areas OA1 and OA2 in the active area AA. That is, the resolution of the optical areas OA1 and OA2 may be lower than the resolution of the general area in the active area AA.

The light-transmitting structure in the optical areas OA1 and OA2 may be formed by patterning a cathode in a region where no subpixels are disposed. At this time, the cathode to be patterned may be removed using a laser, or the cathode may be selectively formed and patterned using a material such as a cathode deposition prevention layer.

In addition, the light-transmitting structure in the optical areas OA1 and OA2 may be formed by separately forming the light-emitting element included in the subpixel and the subpixel driving circuit. In other words, the light-emitting element of the subpixel is positioned on the optical areas OA1 and OA2, and a plurality of transistors constituting the subpixel driving circuit is disposed on the periphery of the optical areas OA1 and OA2, and thus the light-emitting element and the subpixel driving circuit can be electrically connected through a transparent metal layer.

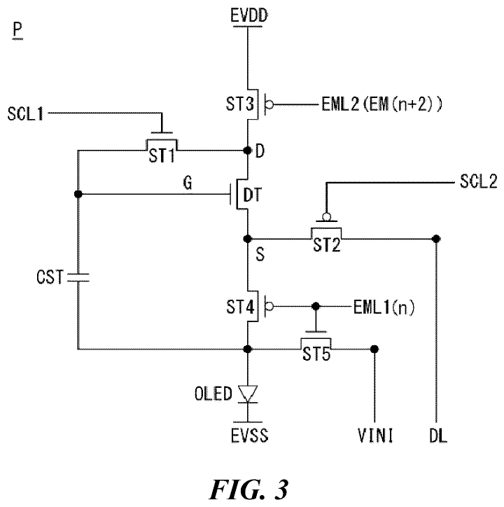

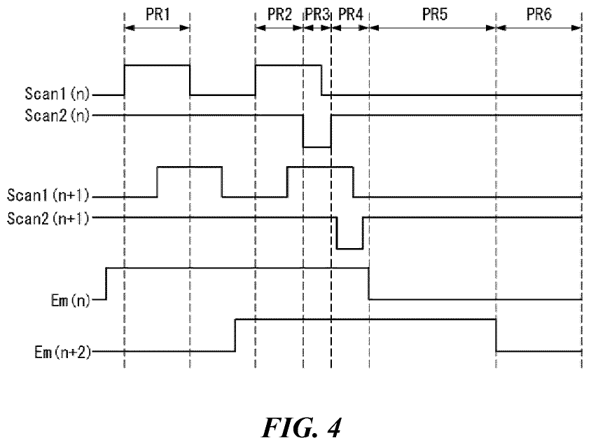

FIG. 3 is a circuit configuration diagram of a subpixel included in the display panel, and FIG. 4 shows driving waveforms of the subpixel illustrated in FIG. 3.

As illustrated in FIG. 3, the sub-pixel P may include a first switching transistor ST1, a second switching transistor ST2, a third switching transistor ST3, a fourth switching transistor ST4, a fifth switching transistor ST5, a driving transistor DT, a capacitor CST, and a light-emitting element OLED.

The first switching transistor ST1 may have a gate electrode connected to the first scan line SCL1, a first electrode connected to a gate node G to which a first electrode of the capacitor CST and a gate electrode of the driving transistor DT are connected, and a second electrode connected to a drain node D to which a second electrode of the third switching transistor ST3 and a first electrode of the driving transistor DT are connected. The first switching transistor ST1 can be turned in response to a first scan signal applied through the first scan line SCL1 to connect the gate node G and the drain node D of the driving transistor DT. The driving transistor DT may be in a diode-connected state whereby the threshold voltage thereof can be sampled when the first switching transistor ST1 is turned on. The first switching transistor ST1 may be defined as a compensation transistor for sampling the threshold voltage of the driving transistor DT.

The second switching transistor ST2 may have a gate electrode connected to the second scan line SCL2, a first electrode connected to a data line DL, and a second electrode connected to a source node S to which a second electrode of the driving transistor DT and a first electrode of the fourth switching transistor ST4 are connected. The second switching transistor ST2 can be turned on in response to a second scan signal applied through the second scan line SCL2 to transmit a data voltage applied through the data line DL to the source node S. The capacitor CST can store the data voltage as the second switching transistor ST2 is turned on. The second switching transistor ST2 may be defined as a data supply transistor for storing a data voltage.

The third switching transistor ST3 may have a gate electrode connected to the second emission control line EML2, a first electrode connected to a high-level voltage line EVDD, and a second electrode connected to the drain node D. The third switching transistor ST3 can be turned on in response to a second emission control signal applied through the second emission control line EML2 to transmit the high-level voltage applied through the high-level voltage line EVDD to the drain node D. The third switching transistor ST3 may be defined as a first emission control transistor for controlling the high-level voltage applied to the driving transistor DT. Meanwhile, the second emission control line EML2 may be an (N+2)th emission control signal line EM(n+2) connected to an (N+2)th subpixel located two scan lines after the illustrated subpixel P. In other words, the third switching transistor ST3 may be connected to the (N+2)th emission control signal line EM(n+2) connected to an output terminal of an (N+2)th emission control signal driver for driving an (N+2)th subpixel located two scan lines after the illustrated subpixel P. However, this is merely an example, and the present disclosure is not limited thereto. For convenience of description, an example in which the second emission control line EML2 is the (N+2)th emission control signal line EM(n+2) connected to the output terminal of the (N+2)th emission control signal driver will be described.

The fourth switching transistor ST4 may have a gate electrode connected to the first emission control line EML1, a first electrode connected to the source node S, and a second electrode connected to a connection node to which a second electrode of the capacitor CST, an anode of the light-emitting diode OLED, and a second electrode of a fifth switching transistor ST5 are connected. The fourth switching transistor ST4 can be turned on in response to a first emission control signal applied through the first emission control line EML1 to transmit a driving current generated from the driving transistor DT to the anode of the light-emitting element OLED. The fourth switching transistor ST4 may be defined as a second emission control transistor for controlling the emission time of the driving transistor DT.

The fifth switching transistor ST5 may have a gate electrode connected to the first emission control line EML1, a first electrode connected to an initialization voltage line VINI, and a second electrode connected to the connection node to which the second electrode of the capacitor CST, a second electrode of the fourth switching transistor ST4, and the anode electrode of the light-emitting element OLED are connected. The fifth switching transistor ST5 can be turned on in response to the first emission control signal applied through the first emission control line EML1 to transmit an initialization voltage applied through the initialization voltage line VINI to the connection node. The fifth switching transistor ST5 may be defined as an initialization voltage transmission transistor for transmitting the initialization voltage to the connection node.

The driving transistor DT may have the gate electrode connected to the gate node G, the first electrode connected to the drain node D, and the second electrode connected to the source node S. The driving transistor DT operates based on a data voltage stored in the capacitor CST and can generate a driving current.

The capacitor CST has the first electrode connected to the gate node G and the second electrode connected to the connection node to which the second electrode of the fourth switching transistor ST4, the second electrode of the fifth switching transistor ST5, and the anode of the light-emitting element OLED are connected. The capacitor CST can store a data voltage, and the stored data voltage can be applied to the gate electrode of the driving transistor DT.

The light-emitting element OLED may have the anode electrode connected to the connection node to which the second electrode of the fourth switching transistor ST4, the second electrode of the fifth switching transistor ST5, and the second electrode of the capacitor CST are connected, and a cathode to which a low-level voltage EVSS is applied. The light-emitting element OLED emits light based on the driving current generated from the driving transistor DT.

Meanwhile, FIG. 3 illustrates an example in which the first switching transistor ST1, the fifth switching transistor ST5, and the driving transistor DT are n-type oxide thin film transistors, and the second switching transistor ST2, the third switching transistor ST3, and the fourth switching transistor ST4 are p-type polycrystalline thin film transistors.

As illustrated in FIG. 3 and FIG. 4, the subpixel P may operate in the order of a first period PR1, a second period PR2, a third period PR3, a fourth period PR4, a fifth period PR5, and a sixth period PR6.

A first scan signal Scan1(n) may be generated as a high voltage during the first period PR1, the second period PR2, and the third period PR3, and may be generated as a low voltage during the fourth period PR4, the fifth period PR5, and the sixth period PR6. “Scan1(n+1)” may be a first scan signal output from a first scan signal generator of an (N+1)th stage located next to an Nth stage that outputs the first scan signal Scan1(n). The first scan signals Scan1(n) and Scan1(n+1) may be generated as a high voltage during the first period PR1 to the third period PR3.

A second scan signal Scan2(n) may be generated as a high voltage during the first period PR1, the second period PR2, the fourth period PR4, the fifth period PR5, and the sixth period PR6, and may be generated as a low voltage during the third period PR3. “Scan2(n+1)” may be a second scan signal output from a second scan signal generator of the (N+1)th stage located next to the Nth stage that outputs the second scan signal Scan2(n).

An emission control signal Em(n) may be generated as a high voltage during the first period PR1 to the fourth period PR4, and may be generated as a low voltage during the fifth period PR5 and the sixth period PR6. “Em(n+2)” may be a first emission control signal output from an emission control signal generator of the (N+2)th stage located at the next stage next to the Nth stage that outputs the emission control signal Em(n).

The first period PR1 may be defined as an initialization period for initializing the gate electrode of the driving transistor DT to a high-level voltage. The second period PR2 may be defined as a period for sampling the threshold voltage of the driving transistor DT. The third period PR3 may be defined as a period for writing a data voltage to the capacitor CST. The fourth period PR4 may be defined as an initialization period for applying an initialization voltage to the anode of the light-emitting element OLED. The fifth period PR5 may be defined as a period in which the source node S of the driving transistor DT and the anode of the light-emitting element OLED have the same voltage level and a current path is cleared before an emission period. The sixth period PR6 may be defined as a period in which the light-emitting element OLED emits light.

Meanwhile, the subpixel illustrated in FIG. 3 and the driving waveforms of FIG. 4 for driving the subpixel should be interpreted as an example of a subpixel that can be driven based on the gate driver described in the present disclosure.

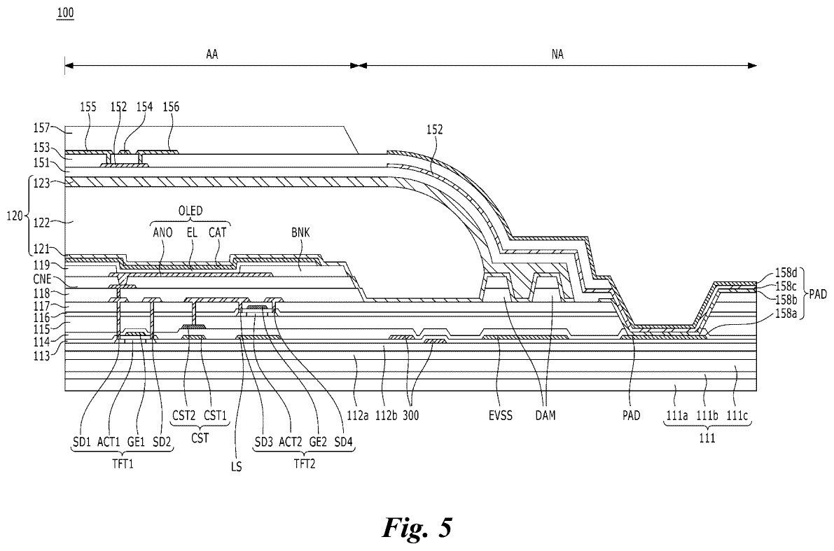

FIG. 5 is a cross-sectional view of a display panel implemented based on the subpixel illustrated in FIG. 3.

As shown in FIG. 5, transistors TFT1 and TFT2 and a first capacitor CST for driving a light-emitting element OLED disposed in the active area AA may be disposed on a substrate 101 of the display panel 100. The transistors TFT1 and TFT2 may include a polycrystalline thin film transistor including a polycrystalline semiconductor material and an oxide thin film transistor including an oxide semiconductor material.

The substrate 111 may include a first substrate layer 111a, a second substrate layer 111b, and a third substrate layer 111c. The first substrate layer 111a and the third substrate layer 111c may be formed using organic films including polyimide, and the second substrate layer 111b located between the first substrate layer 111a and the third substrate layer 111c may be formed using an inorganic film including silicon oxide SiO₂.

A lower buffer layer 112a may be formed on the substrate 111. The lower buffer layer 112a may be formed by laminating multiple layers of silicon oxide SiO₂ to block moisture and the like that may penetrate from the outside. An auxiliary buffer layer 112b may be additionally formed on the lower buffer layer 112a to protect the element from moisture penetration.

The polycrystalline thin film transistor TFT1 may be formed on the substrate 111. The polycrystalline thin film transistor TFT1 may use a polycrystalline semiconductor for an active layer. The polycrystalline thin film transistor TFT1 may include a first active layer ACT1 including a channel through which electrons or holes move, a first gate electrode GE1, a first source electrode SD1, and a first drain electrode SD2. A first gate insulating layer 113 may be disposed between the first gate electrode GE1 and the first active layer ACT1, and the first gate insulating layer 113 may be formed by laminating an inorganic layer such as a silicon oxide (SiO₂) film or a silicon nitride (SiNx) film in a single or multiple layers.

The first active layer ACT1 may include a first channel region, a first source region disposed on one of the first channel region, and a first drain region disposed on the other side of the first channel region. The first source region and the first drain region are conductive regions in which an intrinsic polycrystalline semiconductor material is doped with impurity ions of group 5 or group 3, such as phosphorus (P) or boron (B), at a predetermined concentration. The first channel region is a region in which the intrinsic state of a polycrystalline semiconductor material is maintained and can provide a path for electrons or holes to move.

According to one embodiment, the polycrystalline thin film transistor TFT1 may be implemented in a top gate structure in which the first gate electrode GE1 is positioned on the first active layer ACT1. Accordingly, a first electrode CST1 of the capacitor CST and a light-shielding layer LS included in the oxide thin film transistor TFT2 can be formed of the same material as the first gate electrode GE1. The number of mask processes can be reduced by forming the first gate electrode GE1, the first electrode CST1, and the light-shielding layer LS through one mask process.

The first gate electrode GE1 may be formed of a metal material. For example, the first gate electrode GE1 may be a single layer or multiple layers formed of one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto. A first interlayer insulating layer 114 may be disposed on the first gate electrode GE1. The first interlayer insulating layer 114 may be formed of silicon oxide (SiO₂), silicon nitride (SiNx), or the like.

The display panel 100 may further include an upper buffer layer 115, a second gate insulating layer 116, and a second interlayer insulating layer 117 sequentially laminated on the first interlayer insulating layer 114, and the polycrystalline thin film transistor TFT1 may include a first source electrode SD1 and a first drain electrode SD2 formed on the second interlayer insulating layer 117 and connected to the first source region and the first drain region, respectively.

The first source electrode SD1 and the first drain electrode SD2 may be a single layer or multiple layers formed of one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The upper buffer layer 115 may separate a second active layer ACT2 of the oxide thin film transistor TFT2 formed of an oxide semiconductor material from the first active layer ACT1 formed of a polycrystalline semiconductor material, and may provide a base for forming the second active layer ACT2.

The second gate insulating layer 116 may cover the second active layer ACT2 of the oxide thin film transistor TFT2. Since the second gate insulating layer 116 is formed on the second active layer ACT2 made of an oxide semiconductor material, the second gate insulating layer 116 may be formed using an inorganic film. For example, the second gate insulating layer 116 may be formed of silicon oxide (SiO₂), silicon nitride (SiNx), or the like.

A second gate electrode GE2 may be formed of a metal material. For example, the second gate electrode GE2 may be a single layer or multiple layers formed of one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The oxide thin film transistor TFT2 may be formed on the upper buffer layer 115. The oxide thin film transistor TFT2 may include the second active layer ACT2 formed of an oxide semiconductor material, the second gate electrode GE2 disposed on the second gate insulating layer 116, and a second source electrode SD3 and a second drain electrode SD4 disposed on the second interlayer insulating layer 117. The second active layer ACT2 may be formed of an oxide semiconductor material and may include an intrinsic second channel region that is not doped with impurities, and a second source region and a second drain region that are doped with impurities and thus are conductive.

The oxide thin film transistor TFT2 may further include the light-shielding layer LS positioned below the upper buffer layer 115 and overlapping the second active layer ACT2. The light-shielding layer LS may block light incident on the second active layer ACT2 to secure the reliability of the oxide thin film transistor TFT2. The light-shielding layer LS is formed of the same material as the first gate electrode GE1 and may be formed on the upper surface of the first gate insulating layer 113. The light-shielding layer LS may also be electrically connected to the second gate electrode GE2 to form a dual gate.

The second source electrode SD3 and the second drain electrode SD4 may be simultaneously formed of the same material on the second interlayer insulating layer 117 together with the first source electrode SD1 and the first drain electrode SD2, thereby reducing the number of mask processes.

Meanwhile, the capacitor CST may be formed by disposing a second electrode CST2 on the first interlayer insulating layer 114 to overlap the first electrode CST1. The second electrode CST2 may be a single layer or multiple layers made of, for example, one of molybdenum (Mo), aluminum (Al), chromium (Cr), gold (Au), titanium (Ti), nickel (Ni), neodymium (Nd), and copper (Cu), or an alloy thereof.

The capacitor CST may store a data voltage applied through a data line DL for a predetermined period of time. The capacitor CST may include two electrodes facing each other and a dielectric disposed therebetween. The first interlayer insulating layer 114 may be positioned between the first electrode CST1 and the second electrode CST2.

The first electrode CST1 or the second electrode CST2 of the capacitor CST may be electrically connected to the second source electrode SD3 or the second drain electrode SD4 of the oxide thin film transistor TFT2. However, the present disclosure is not limited thereto, and the connection relationship of the capacitor CST may change depending on the subpixel driving circuit.

A first planarization layer 118 and a second planarization layer 119 may be sequentially disposed on the subpixel driving circuit to planarize the surface. The first planarization layer 118 and the second planarization layer 119 may be organic films formed of, for example, polyimide or acrylic resin. The light-emitting element OLED may be formed on the second planarization layer 119.

The light-emitting element OLED may include an anode ANO, a cathode CAT, and an emission layer EL disposed between the anode ANO and the cathode CAT. In the case of a subpixel driving circuit that commonly uses a low level voltage applied to the cathode CAT, the anode ANO is disposed as a separate electrode for each subpixel. On the other hand, in the case of a subpixel driving circuit that commonly uses a high level voltage, the cathode CAT may be disposed as a separate electrode for each subpixel.

The light-emitting element OLED may be electrically connected to a driving element through an intermediate electrode CNE disposed on the first planarization layer 118. For example, the anode ANO of the light-emitting element OLED and the first source electrode SD1 of the polycrystalline thin film transistor TFT1 constituting the subpixel driving circuit may be connected to each other by the intermediate electrode CNE.

The anode ANO may be connected to the intermediate electrode CNE exposed through a contact hole penetrating the second planarization layer 119. The intermediate electrode CNE may be connected to the first source electrode SD1 exposed through a contact hole penetrating the first planarization layer 118.

The intermediate electrode CNE may serve as a medium connecting the first source electrode SD1 and the anode ANO. The intermediate electrode CNE may be formed of a conductive material such as copper (Cu), silver (Ag), molybdenum (Mo), or titanium (Ti).

The anode ANO may be formed in a multilayer structure including a transparent conductive film and an opaque conductive film with high reflection efficiency. The transparent conductive film may be formed of a material having a relatively high work function value, such as indium-tin-oxide (ITO) or indium-zinc-oxide (IZO), and the opaque conductive film may be formed in a single-layer or multilayer structure including aluminum (Al), silver (Ag), copper (Cu), lead (Pb), molybdenum (Mo), titanium (Ti), or an alloy thereof. For example, the anode ANO may be formed in a structure in which a transparent conductive film, an opaque conductive film, and a transparent conductive film are sequentially laminated, or a structure in which a transparent conductive film and an opaque conductive film are sequentially laminated. The emission layer EL is formed by sequentially or reversely laminating a hole-related layer, an organic emission layer, and an electron-related layer on the anode ANO.

A bank layer BNK may be a subpixel defining film that exposes the anode ANO of each subpixel. The bank layer BNK may be formed of an opaque material (e.g., black) to prevent or reduce optical interference between adjacent subpixels. In this case, the bank layer BNK may include a light-shielding material made of at least one of a color pigment, organic black, and carbon.

The cathode CAT may be formed on the upper surface and side surface of the emission layer EL while facing the anode ANO with the emission layer EL interposed therebetween. The cathode CAT may be formed to cover the entire active area AA. When applied to a top-emitting organic light-emitting display device, the cathode CAT may be formed of a transparent conductive film such as indium-tin-oxide (ITO) or indium-zinc-oxide (IZO).

An encapsulation layer 120 that suppresses moisture penetration may be additionally disposed on the cathode CAT. The encapsulation layer 120 may block moisture or oxygen from penetrating into the emission layer EL that is vulnerable to moisture or oxygen from the outside. To this end, the encapsulation layer 120 may include at least one inorganic encapsulation layer and at least one organic encapsulation layer, but the present disclosure is not limited thereto. The encapsulation layer 120 may include a first encapsulation layer 121, a second encapsulation layer 122, and a third encapsulation layer 123 that are sequentially laminated.

The first encapsulation layer 121 and the third encapsulation layer 123 may be formed of an inorganic insulating material capable of low-temperature deposition, such as silicon nitride (SiNx), silicon oxide (SiOx), silicon oxynitride (SiON), or aluminum oxide (Al₂O₃). Since the first encapsulation layer 121 and the third encapsulation layer 123 are deposited in a low-temperature environment, the emission layer EL, which is vulnerable to high temperatures, can be prevented or reduced from being damaged during the deposition process of the first encapsulation layer 121 and the third encapsulation layer 123.

The second encapsulation layer 122 serves as a buffer to relieve stress between layers due to bending of the display device 10 and can flatten steps between layers. The second encapsulation layer 122 may be formed on the substrate 111 on which the first encapsulation layer 121 is formed, using a non-photosensitive organic insulating material such as an acrylic resin, an epoxy resin, a phenolic resin, a polyamide resin, a polyimide resin, and polyethylene or silicon oxycarbon (SiOC), or a photosensitive organic insulating material such as photoreactive acrylic, but the present disclosure is not limited thereto.

When the second encapsulation layer 122 is formed using an inkjet method, a dam DAM may be formed to prevent or reduce the second encapsulation layer 122 in a liquid form from spreading to the edge of the substrate 111. The dam DAM may be disposed closer to the edge of the substrate 111 than the second encapsulation layer 122. According to the dam DAM, the second encapsulation layer 122 can be prevented or reduced from spreading to a pad area where a conductive pad is disposed at the outermost edge of the substrate 111.

The dam DAM is designed to prevent or reduce spreading of the second encapsulation layer 122, but if the second encapsulation layer 122 is formed to exceed the height of the dam DAM during the process, the second encapsulation layer 122, which is an organic layer, can be exposed to the outside, and thus moisture, etc., can easily penetrate into the light-emitting element. Therefore, to prevent or reduce this, at least ten dams DAM may be formed.

The dam DAM may be disposed on the second interlayer insulating layer 117 of the non-active area NA. The dam DAM may be formed simultaneously with the first planarization layer 118 and the second planarization layer 119. A lower layer of the dam DAM may be formed simultaneously with formation of the first planarization layer 118, and an upper layer of the dam DAM may be formed simultaneously with formation of the second planarization layer 119, such that the dam DAM can be formed in a laminated structure. Accordingly, the dam DAM may be formed of the same materials as the first planarization layer 118 and the second planarization layer 119, but the present disclosure is not limited thereto.

The dam DAM may be formed to overlap the low-level voltage line EVSS. For example, the low-level voltage line EVSS may be located below the area where the dam DAM is located in the non-active area NA. The low-level voltage line EVSS may be disposed outside the gate driver 300 and may surround the active area AA. For example, the low-level voltage line EVSS may be made of the same material as the first gate electrode GE1, but is not limited thereto and may be made of the same material as the second electrode CST2 or the first source and drain electrodes SD1 and SD2. The low-level voltage line EVSS may be electrically connected to the cathode CAT to apply the low-level voltage EVSS to a plurality of subpixels included in the active area AA.

A touch layer may be disposed on the encapsulation layer 120. The touch layer may include a touch sensor metal layer including touch electrode connection lines 152 and 154 and touch electrodes 155 and 156.

A touch buffer film 151 can block chemicals (developing solution or etching solution, etc.) used in the manufacturing process of the touch sensor metal layer disposed on the touch buffer film 151 or moisture from the outside from penetrating into the emission layer EL containing an organic material. Accordingly, the touch buffer film 151 can prevent or reduce damage to the emission layer EL that is vulnerable to chemicals or moisture.

The touch buffer film 151 may be formed of an organic insulating material that can be formed at a low temperature (e.g., 100° C. or lower) to prevent or reduce damage to the emission layer EL containing an organic material vulnerable to high temperatures and has a low dielectric constant of 1 to 3. For example, the touch buffer film 151 may be formed of an acrylic series, an epoxy series, or a siloxane series material. The touch buffer film 151 having a planarization performance due to an organic insulating material can prevent or reduce damage to the encapsulation layer 120 due to bending of the device and breakage of the touch sensor metal formed on the touch buffer film 151.

According to the mutual-capacitance-based touch sensor structure, the touch electrodes 155 and 156 may be disposed on the touch buffer film 151 to cross each other. The touch electrode connection lines 152 and 154 can electrically connect the touch electrodes 155 and 156. The touch electrode connection lines 152 and 154 and the touch electrodes 155 and 156 may be positioned in different layers with a touch insulating film 153 interposed therebetween. The touch electrode connection lines 152 and 154 may be disposed to overlap the bank layer 165, thereby preventing or reducing the aperture ratio from being reduced.

The touch electrodes 155 and 156 may be electrically connected to a touch driving circuit (not shown) via a touch pad through a part of the touch electrode connection line 152 that passes through the upper and side surfaces of the encapsulation layer 120 and the upper and side surfaces of the dam DAM. The part of the touch electrode connection line 152 may receive a touch driving signal from the touch driving circuit and transmit the same to the touch electrodes 155 and 156, and may also transmit a touch sensing signal from the touch electrodes 155 and 156 to the touch driving circuit.

A touch passivation film 157 may be disposed on the touch electrodes 155 and 156. Although the touch passivation film 157 is illustrated as being disposed only on the touch electrodes 155 and 156, the present disclosure is not limited thereto, and the touch passivation film 157 may extend to the front or back of the dam DAM and may also be disposed on the touch electrode connection line 152. A color filter (not illustrated) may be disposed on the encapsulation layer 120, and the color filter may be located on the touch layer or between the encapsulation layer 120 and the touch layer.

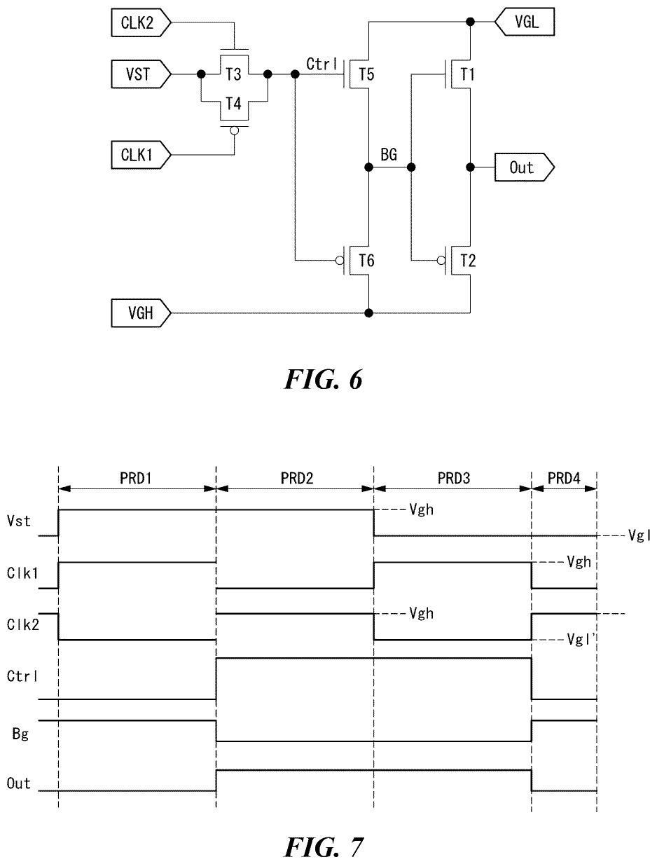

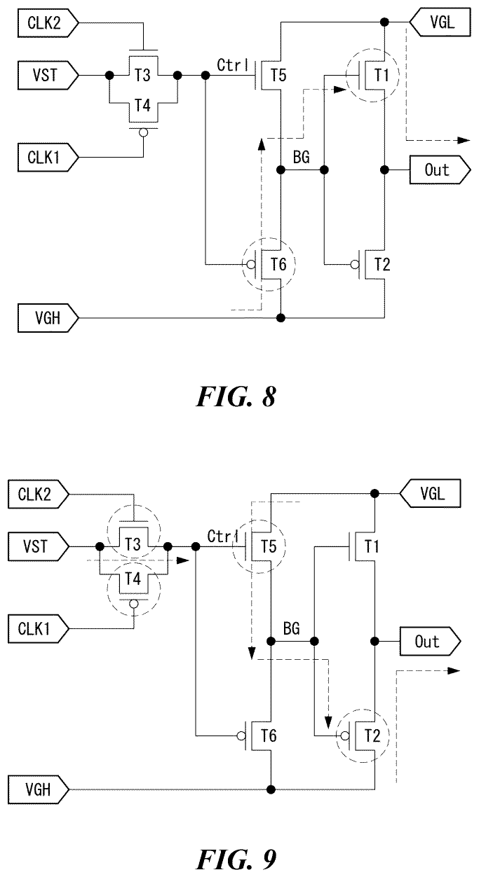

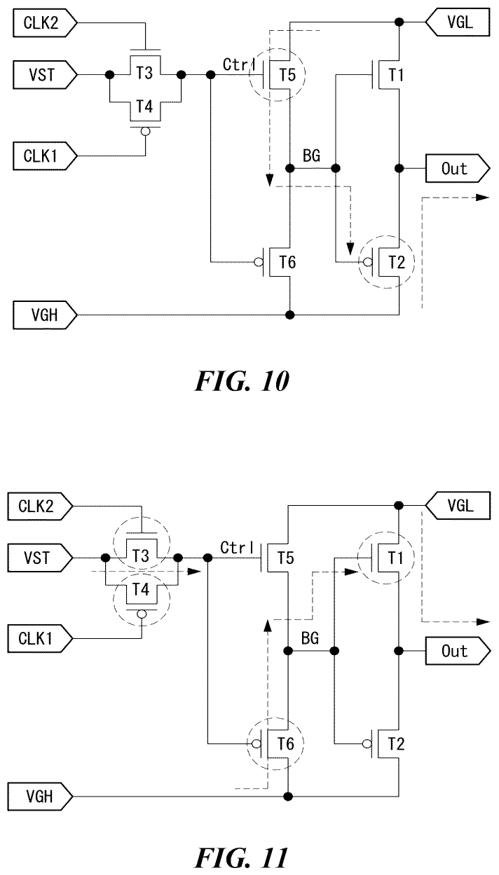

FIG. 6 is a circuit diagram of an emission control signal driver according to a first embodiment, FIG. 7 shows driving waveforms of the emission control signal driver illustrated in FIG. 6, and FIG. 8 to FIG. 11 show operation states of the emission control signal driver according to the driving waveforms of FIG. 7.

As illustrated in FIG. 6, an Nth stage (N being an integer equal to or greater than 1) of the emission control signal driver according to the first embodiment may include a first transistor T1, a second transistor T2, a third transistor T3, a fourth transistor T4, a fifth transistor T5, and a sixth transistor T6. According to the first embodiment, the Nth stage of the emission control signal driver may be implemented using CMOS transistors, which will be described as follows.

The first transistor T1 may have a gate electrode connected to a first node BG, a first electrode connected to a gate low voltage line VGL, and a second electrode connected to an output terminal Out. The first transistor T1 may be an n-type oxide thin film transistor. The first transistor T1 may be turned on based on a high voltage (or first voltage) charged at the first node BG to output a gate low voltage applied through the gate low voltage line VGL as an emission control signal at the gate low voltage (or turn-on voltage). The first transistor T1 may be defined as a first output transistor that outputs an emission control signal at the gate low voltage (or turn-on voltage).

The second transistor T2 may have a gate electrode connected to the first node BG, a first electrode connected to a gate high voltage line VGH, and a second electrode connected to the output terminal Out. The second transistor T2 may be a p-type polycrystalline thin film transistor. The second transistor T2 may be turned on based on a low voltage (or second voltage) charged at the first node BG to output a gate high voltage applied through the gate high voltage line VGH as an emission control signal at the gate high voltage (or turn-off voltage). The second transistor T2 may be defined as a second output transistor that outputs an emission control signal at the gate high voltage (or turn-off voltage).

The third transistor T3 may have a gate electrode connected to a second clock signal line CLK2, a first electrode connected to a start signal line VST (or an output terminal of an (N−1)th stage (i.e., the preceding stage), where N is an integer equal to or greater than 1), and a second electrode connected to a second node Ctrl. The third transistor T3 may be an n-type oxide thin film transistor. The third transistor T3 may be turned on based on a second clock signal at a high voltage applied through the second clock signal line CLK2 to transmit a start signal applied through the start signal line VST to the second node Ctrl. The third transistor T3 may be defined as a (2-1)th node control transistor that controls the second node Ctrl.

The fourth transistor T4 may have a gate electrode connected to a first clock signal line CLK1, a first electrode connected to the start signal line VST (or the output terminal of the (N−1)th stage, where N is an integer equal to or greater than 1), and a second electrode connected to the second node Ctrl. The fourth transistor T4 may be a p-type polycrystalline thin film transistor. The fourth transistor T4 may be turned on based on a first clock signal at a low voltage applied through the first clock signal line CLK1 to transmit the start signal applied through the start signal line VST to the second node Ctrl. The fourth transistor T4 may be defined as a (2-2)th node control transistor that controls the second node Ctrl.

The fifth transistor T5 may have a gate electrode connected to the second node Ctrl, a first electrode connected to the gate low voltage line VGL, and a second electrode connected to the first node BG. The fifth transistor T5 may be an n-type oxide thin film transistor. The fifth transistor T5 may be turned on based on a high voltage start signal (or third voltage) charged at the second node Ctrl to transmit the gate low voltage applied through the gate low voltage line VGL to the first node BG. The fifth transistor T5 may be defined as a (1-1)th control transistor that controls the first node BG.

The sixth transistor T6 may have a gate electrode connected to the second node Ctrl, a first electrode connected to the gate high voltage line VGH, and a second electrode connected to the first node BG. The sixth transistor T6 may be a p-type polycrystalline thin film transistor. The sixth transistor T6 may be turned on based on a low voltage start signal (or fourth voltage) charged at the second node Ctrl to transmit the gate high voltage applied through the gate high voltage line VGH to the first node BG. The sixth transistor T6 may be defined as a (1-2)th control transistor that controls the first node BG.

Meanwhile, the emission control signal driver according to the first embodiment may be disposed in the non-active area outside the first scan signal generators SC1(1) to SC1(n) and the second scan signal generators SC2(1) to SC2(n), as illustrated in FIG. 2. Accordingly, the start signal line VST, the first clock signal line CLK1, and the second clock signal line CLK2 connected to the emission control signal driver may be disposed outside the start signal line and the clock signal lines for driving the first scan signal generators SC1(1) to SC1(n) and the second scan signal generators SC2(1) to SC2(n).

As illustrated in FIG. 7, the Nth stage of the emission control signal driver illustrated in FIG. 6 may operate in the order of a first period PRD1, a second period PRD2, a third period PRD3, and a fourth period PRD4.

A start signal Vst may be generated as a gate high voltage Vgh during the first period PRD1 and the second period PRD2 and may be generated as a gate low voltage Vgl during the third period PRD3 and the fourth period PRD4.

A first clock signal Clk1 may be generated as the gate high voltage Vgh during the first period PRD1, as the gate low voltage Vgl during the second period PRD2, as the gate high voltage Vgh during the third period PRD3, and as the gate low voltage Vgl during the fourth period PRD4.

A second clock signal Clk2 may be generated as a second gate low voltage Vgl′ during the first period PRD1, as the gate high voltage Vgh during the second period PRD2, as a second gate low voltage Vgl′ during the third period PRD3, and as the gate high voltage Vgh during the fourth period PRD4.

As illustrated in FIG. 7 and FIG. 8, during the first period PRD1, the start signal Vst and the first clock signal Clk1 may be applied as the gate high voltage Vgh, and the second clock signal Clk2 may be applied as the gate low voltage Vgl.

During the first period PRD1, the third transistor T3 and the fourth transistor T4 is turned off as the first clock signal Clk1 at the gate high voltage Vgh and the second clock signal Clk2 at the second gate low voltage Vgl′ are applied.

The second node Ctrl maintains a low voltage due to the low voltage start signal applied during the previous period. Accordingly, the sixth transistor T6 can be turned on based on a second node voltage Ctr that is the low voltage charged at the second node Ctrl to transmit the gate high voltage applied through the gate high voltage line VGH to the first node BG. In addition, the first transistor T1 can be turned on based on a first node voltage Bg that is the high voltage charged at the first node BG to output the gate low voltage applied through the gate low voltage line VGL as an emission control signal Out at the gate low voltage.

As illustrated in FIG. 7 and FIG. 9, when the first clock signal Clk1 at the gate low voltage Vgl and the second clock signal Clk2 at the gate high voltage Vgh are applied during the second period PRD2, the third transistor T3 and the fourth transistor T4 are turned on.

The second node Ctrl is charged to a high voltage due to the high voltage start signal transmitted through the third transistor T3 and the fourth transistor T4. Accordingly, the fifth transistor T5 can be turned on based on the second node voltage Ctr that is the high voltage charged at the second node Ctrl to transmit the gate low voltage applied through the gate low voltage line VGL to the first node BG. In addition, the second transistor T2 can be turned on based on the first node voltage Bg that is the low voltage charged at the first node BG to output the gate high voltage applied through the gate high voltage line VGH as the emission control signal Out at the gate high voltage.

As illustrated in FIG. 7 and FIG. 10, the third transistor T3 and the fourth transistor T4 is turned off when the first clock signal Clk1 at the gate high voltage Vgh and the second clock signal Clk2 at the second gate low voltage Vgl′ are applied during the third period PRD3.

The second node Ctrl maintains a high voltage due to the high voltage start signal applied during the previous period. Accordingly, the fifth transistor T5 can be turned on based on the second node voltage Ctr that is the high voltage charged at the second node Ctrl to transmit the gate low voltage applied through the gate low voltage line VGL to the first node BG. In addition, the second transistor T2 can be turned on based on the first node voltage Bg that is the low voltage charged at the first node BG to output the gate high voltage applied through the gate high voltage line VGH as the emission control signal Out at the gate high voltage.

As illustrated in FIG. 7 and FIG. 11, the third transistor T3 and the fourth transistor T4 are turned on when the first clock signal Clk1 at the gate low voltage Vgl and the second clock signal Clk2 at the gate high voltage Vgh are applied during the fourth period PRD4.

The second node Ctrl is charged to a low voltage due to the low voltage start signal transmitted through the third transistor T3 and the fourth transistor T4. Accordingly, the sixth transistor T6 can be turned on based on the second node voltage Ctr that is the low voltage charged at the second node Ctrl to transmit the gate high voltage applied through the gate high voltage line VGH to the first node BG. In addition, the first transistor T1 can be turned on based on the first node voltage Bg that is the high voltage charged at the first node BG to output the gate low voltage applied through the gate low voltage line VGL as the emission control signal Out at the gate low voltage.

Referring to FIG. 7 to FIG. 11, the Nth stage of the emission control signal driver according to the first embodiment can operate based on the first clock signal Clk1 and the second clock signal Clk2 that are generated by toggling at opposite levels (Clk1 and Clk2 of duty 50% waveforms with phases inverted with respect to each other). Here, the first clock signal Clk1 and the second clock signal Clk2 may be generated as a high voltage based on the same level of gate high voltage Vgh, and may be generated as low voltages based on the gate low voltage Vgl and the second gate low voltage Vgl′ having different levels.

For example, the gate high voltage Vgh may have a level of 5 V, the gate low voltage Vgl may have a level of −2 V, and the second gate low voltage Vgl′ may have a level of −5 V. According to the above example, the first clock signal Clk1 may toggle between a low voltage and a high voltage in the range of −2 V to 5 V. The second clock signal Clk2 may toggle between a low voltage and a high voltage in the range of −5 V to 5 V.

When the stages of the emission control signal driver are configured as shown in FIG. 6 and the first clock signal Clk1 and the second clock signal Clk2 are generated at different levels and applied, the operational reliability, operational stability, and threshold voltage margin (Vth margin) of the third transistor T3 configured as an n-type oxide thin film transistor can be secured.

The third transistor T3 configured as an n-type oxide thin film transistor may be turned on in a voltage transition period (period of transition from a low voltage to a high voltage) of the start signal when toggling delay of the second clock signal occurs. In this case, the stages of the emission control signal driver may perform an undesired operation or an abnormal operation.

In view of this, if the low voltage level of the second clock signal that controls the operation of the third transistor T3 is set to the second gate low voltage Vgl′ lower than the gate low voltage Vgl corresponding to the low voltage level of the first clock signal, the problem due to the toggling delay can be reduced or improved.

In other words, the first embodiment can reduce or improved the problem caused by toggling delay that may occur in the voltage transition period (period of transition from a low voltage to a high voltage) of the start signal by improving the turn-off characteristics of the third transistor T3 based on the second clock signal set to the second gate low voltage Vgl′ (gate low voltage having a different level) lower than the gate low voltage Vgl.

In addition, the first embodiment can reduce power consumption (reduce power consumption according to low Vpp) by configuring the emission control signal driver based on CMOS transistors and implementing the first transistor T1 that controls output as an oxide thin film transistor to secure a turn-on condition (Turn on Vgs) in which a high peak-to-peak voltage Vpp as in the case of bootstrap is not generated.

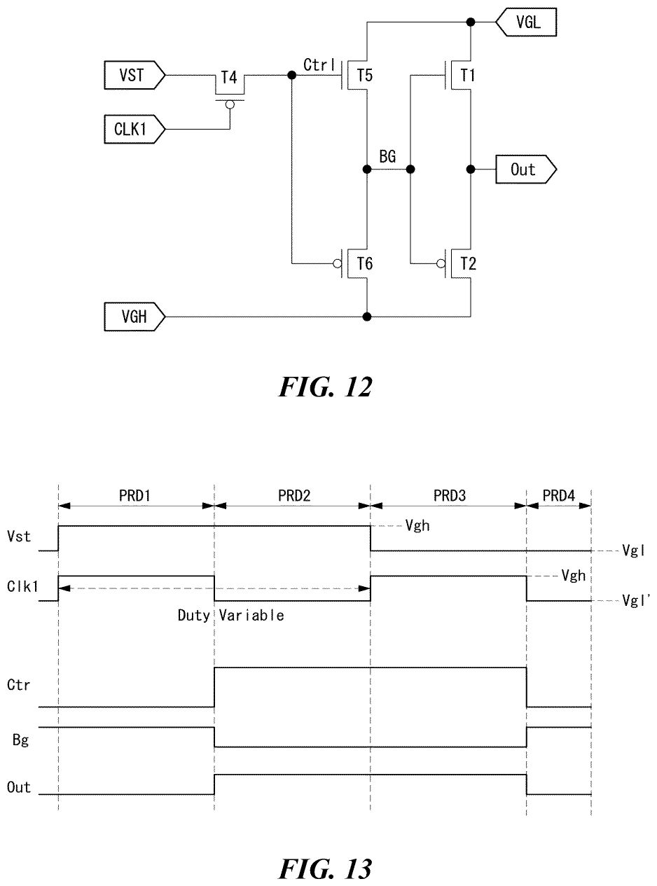

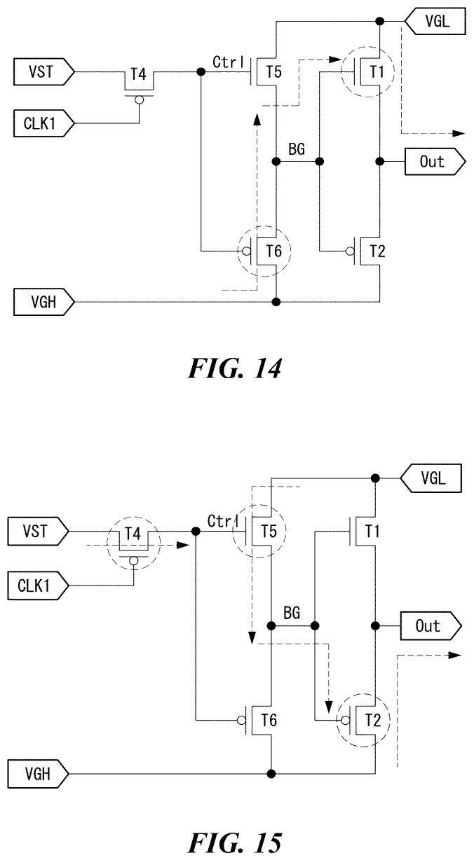

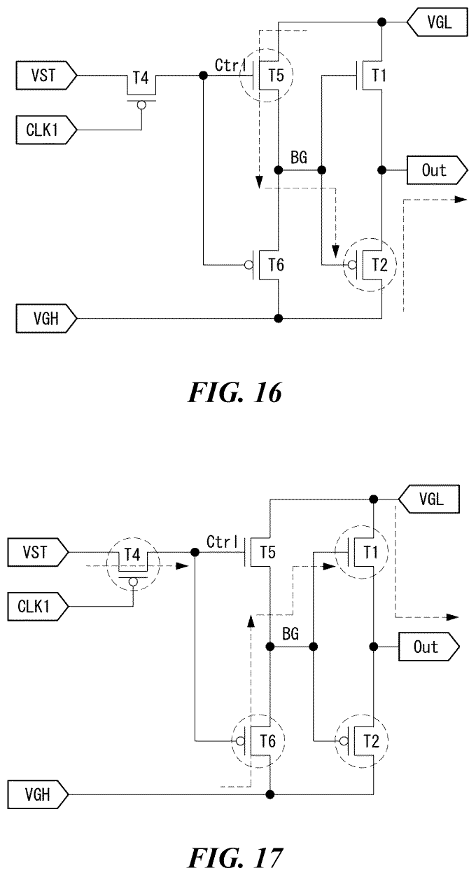

FIG. 12 is a circuit configuration diagram of an emission control signal driver according to a second embodiment, FIG. 13 shows driving waveforms of the emission control signal driver illustrated in FIG. 12, and FIG. 14 to FIG. 17 show operation states of the emission control signal driver according to the driving waveforms of FIG. 14.

As illustrated in FIG. 12, the Nth stage (N being an integer equal to or greater than 1) of the emission control signal driver according to the second embodiment may include a first transistor T1, a second transistor T2, a fourth transistor T4, a fifth transistor T5, and a sixth transistor T6. According to the second embodiment, the Nth stage of the emission control signal driver may be implemented using CMOS transistors, which will be described as follows.

The first transistor T1 may have a gate electrode connected to a first node BG, a first electrode connected to a gate low voltage line VGL, and a second electrode connected to an output terminal Out. The first transistor T1 may be an n-type oxide thin film transistor. The first transistor T1 may be turned on based on a high voltage (or first voltage) charged at the first node BG to output a gate low voltage applied through the gate low voltage line VGL as an emission control signal at the gate low voltage (or turn-on voltage). The first transistor T1 may be defined as a first output transistor that outputs an emission control signal at the gate low voltage (or turn-on voltage).

The second transistor T2 may have a gate electrode connected to the first node BG, a first electrode connected to a gate high voltage line VGH, and a second electrode connected to the output terminal Out. The second transistor T2 may be a p-type polycrystalline thin film transistor. The second transistor T2 may be turned on based on a low voltage (or second voltage) charged at the first node BG to output the gate high voltage applied through the gate high voltage line VGH as an emission control signal at the gate high voltage (or turn-off voltage). The second transistor T2 may be defined as a second output transistor that outputs an emission control signal at the gate high voltage (or turn-off voltage).

The fourth transistor T4 may have a gate electrode connected to a first clock signal line CLK1, a first electrode connected to a start signal line VST (or an output terminal of an (N−1)th stage, where N is an integer equal to or greater than 1), and a second electrode connected to a second node Ctrl. The fourth transistor T4 may be a p-type polycrystalline thin film transistor. The fourth transistor T4 may be turned on based on a first clock signal at a low voltage applied through the first clock signal line CLK1 to transmit a start signal applied through the start signal line VST to the second node Ctrl. The fourth transistor T4 may be defined as a node control transistor that controls the second node Ctrl.

The fifth transistor T5 may have a gate electrode connected to the second node Ctrl, a first electrode connected to the gate low voltage line VGL, and a second electrode connected to the first node BG. The fifth transistor T5 may be an n-type oxide thin film transistor. The fifth transistor T5 may be turned on based on a high voltage start signal (or third voltage) charged at the second node Ctrl to transmit the gate low voltage applied through the gate low voltage line VGL to the first node BG. The fifth transistor T5 may be defined as a (1-1)th control transistor that controls the first node BG.

The sixth transistor T6 may have a gate electrode connected to the second node Ctrl, a first electrode connected to the gate high voltage line VGH, and a second electrode connected to the first node BG. The sixth transistor T6 may be a p-type polycrystalline thin film transistor. The sixth transistor T6 may be turned on based on a low voltage start signal (or fourth voltage) charged at the second node Ctrl to transmit the gate high voltage applied through the gate high voltage line VGH to the first node BG. The sixth transistor T6 may be defined as a (1-2)th control transistor that controls the first node BG.

As illustrated in FIG. 13, the Nth stage of the emission control signal driver illustrated in FIG. 12 may operate in the order of a first period PRD1, a second period PRD2, a third period PRD3, and a fourth period PRD4.

A start signal Vst may be generated as a gate high voltage Vgh during the first period PRD1 and the second period PRD2, and may be generated as a gate low voltage Vgl during the third period PRD3 and the fourth period PRD4.

A first clock signal Clk1 may be generated as a gate high voltage Vgh during the first period PRD1, as a second gate low voltage Vgl′ during the second period PRD2, as the gate high voltage Vgh during the third period PRD3, and as the second gate low voltage Vgl′ during the fourth period PRD4.

As illustrated in FIG. 13 and FIG. 14, the start signal Vst and the first clock signal Clk1 may be applied as the gate high voltage Vgh during the first period PRD1.

As the first clock signal Clk1 at the gate high voltage Vgh is applied during the first period PRD1, the fourth transistor T4 can be turned off. The second node Ctrl can maintain a low voltage due to the low voltage start signal applied during the previous period. Accordingly, the sixth transistor T6 can be turned on based on a second node voltage Ctr corresponding to the low voltage charged at the second node Ctrl to transmit the gate high voltage applied through the gate high voltage line VGH to the first node BG.

In addition, the first transistor T1 can be turned on based on a first node voltage Bg corresponding to the high voltage charged at the first node BG to output the gate low voltage applied through the gate low voltage line VGL as an emission control signal Out at the gate low voltage.

As illustrated in FIG. 13 and FIG. 15, the fourth transistor T4 is turned on when the first clock signal Clk1 at the second gate low voltage Vgl′ is applied during the second period PRD2. The second node Ctrl is charged to a high voltage due to the high voltage start signal transmitted through the fourth transistor T4. Accordingly, the fifth transistor T5 can be turned on based on the second node voltage Ctr corresponding to the high voltage charged at the second node Ctrl to transmit the gate low voltage applied through the gate low voltage line VGL to the first node BG. In addition, the second transistor T2 can be turned on based on the first node voltage Bg corresponding to the low voltage charged at the first node BG to output the gate high voltage applied through the gate high voltage line VGH as the emission control signal Out at the gate high voltage.

As illustrated in FIG. 13 and FIG. 16, the fourth transistor T4 is turned off when the first clock signal Clk1 at the gate high voltage Vgh is applied during the third period PRD3. The second node Ctrl maintains a high voltage due to the high voltage start signal applied during the previous period. Accordingly, the fifth transistor T5 can be turned on based on the second node voltage Ctr corresponding to the high voltage charged at the second node Ctrl to transmit the gate low voltage applied through the gate low voltage line VGL to the first node BG. In addition, the second transistor T2 can be turned on based on the first node voltage Bg corresponding to the low voltage charged at the first node BG to output the gate high voltage applied through the gate high voltage line VGH as the emission control signal Out at the gate high voltage.

As illustrated in FIG. 13 and FIG. 17, the fourth transistor T4 is turned on when the first clock signal Clk1 at the second gate low voltage Vgl′ is applied during the fourth period PRD4. The second node Ctrl is charged to a low voltage due to the low voltage start signal transmitted through the fourth transistor T4. Accordingly, the sixth transistor T6 can be turned on based on the second node voltage Ctr corresponding to the low voltage charged at the second node Ctrl to transmit the gate high voltage applied through the gate high voltage line VGH to the first node BG. In addition, the first transistor T1 can be turned on based on the first node voltage Bg corresponding to the high voltage charged at the first node BG to output the gate low voltage applied through the gate low voltage line VGL as the emission control signal Out at the gate low voltage.

Referring to FIG. 13 to FIG. 17, the Nth stage of the emission control signal driver according to the second embodiment can operate based on the first clock signal Clk1 that is generated by toggling between a high voltage and a low voltage. Here, the first clock signal Clk1 is generated as a high voltage based on the gate high voltage Vgh, and may also be generated a low voltage based on the separately (independently) generated second gate low voltage Vgl′.

For example, the gate high voltage Vgh may have a level of 5 V, the gate low voltage Vgl may have a level of −2 V, and the second gate low voltage Vgl′ may have a level of −5 V. According to the above example, the first clock signal Clk1 may toggle between a low voltage and a high voltage in the range of −5 V to 5 V.

When the stages of the emission control signal driver are configured as in FIG. 12 and the first clock signal Clk1 is set to the second gate low voltage Vgl′ and applied, the operational reliability, operational stability, and threshold voltage margin (Vth margin) of the fourth transistor T4 corresponding to the p-type oxide thin film transistor can be secured. In addition, by improving the turn-on characteristics of the fourth transistor T4, a problem caused by toggling delay that may occur in a voltage transition period (period of transition from a low voltage to a high voltage) of the start signal can be reduced or improved. In addition, since an n-type oxide thin film transistor such as the third transistor T3 in FIG. 6 can be eliminated, the area occupied by the gate driver can be reduced, and margin management can be facilitated.

In addition, the second embodiment configures the emission control signal driver based on CMOS transistors and implements the first transistor T1 that controls output as an oxide thin film transistor to secure a turn-on condition (Turn on Vgs) in which a high peak-to-peak voltage Vpp like a bootstrap is not generated, and thus power consumption can be reduced (power consumption can be reduced according to low Vpp).

In addition, according to the second embodiment, the first clock signal Clk1 can be toggled between a high voltage and a low voltage between the first period PRD1 and the second period PRD2, that is, the duty is variable.

As a result, the second embodiment can more freely configure and change clock signal generation timing by eliminating the third transistor in the first embodiment and not using the second clock signal. That is, since the second embodiment can more freely configure driving waveforms (increasing the degree of freedom of the clock signal waveform), a flexible driving method can be applied depending on the characteristics of transistors or the characteristics of the device.

The present disclosure has the effect of minimizing or reducing power consumption by configuring an emission control signal driver based on CMOS transistors and implementing a transistor that controls output using an oxide thin film transistor to secure a turn-on condition in which a high peak-to-peak voltage Vpp such as a bootstrap is not generated. In addition, the present disclosure has the effect of minimizing or improving a problem caused by toggling delay by driving transistors based on a gate low voltage divided into different levels in the emission control signal driver. Further, the present disclosure has the effect of providing a gate driver including an emission control signal driver capable of securing operational reliability, operational stability, and a threshold voltage margin. In addition, the present disclosure has the effect of minimizing or reducing the area occupied by the gate driver and facilitating margin management by eliminating some oxide thin film transistors when implementing the emission control signal driver.

It will be apparent to those skilled in the art that various modifications and variations can be made in the present disclosure without departing from the technical idea or scope of the present disclosure. Thus, it is intended that the present disclosure cover the modifications and variations of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed

description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel configured to display an image; and
a gate driver having an emission control signal generator configured to supply an emission control signal to the display panel,
wherein the emission control signal generator comprises:
a first output transistor configured to be turned on based on a first voltage charged at a first node to output an emission control signal at a turn-on voltage;
a second output transistor configured to be turned on based on a second voltage charged at the first node and different from the first voltage to output an emission control signal at a turn-off voltage;
a 1-1th control transistor configured to be turned on based on a third voltage charged at a second node to control the first voltage to be charged at the first node;
a 1-2th control transistor configured to be turned on based on a fourth voltage charged at the second node and different from the third voltage to control the second voltage to be charged at the first node; and
a node control transistor configured to be turned on based on at least one clock signal to transmit a signal for forming the third voltage or the fourth voltage to the second node.

2. The display device of claim 1, wherein the clock signal is generated based on a gate high voltage corresponding to the turn-off voltage and a second gate low voltage lower than a gate low voltage corresponding to the turn-on voltage and the clock signal is toggled between a high voltage and a low voltage.

3. The display device of claim 1, wherein the first output transistor and the second output transistor are CMOS transistors.

4. The display device of claim 1, wherein the first output transistor has a gate electrode connected to the first node, a first electrode connected to a gate low voltage line, and a second electrode connected to an output terminal of the emission control signal generator, and the second output transistor has a gate electrode connected to the first node, a first electrode connected to a gate high voltage line, and a second electrode connected to the output terminal of the emission control signal generator.

5. The display device of claim 1, wherein the node control transistor comprises a gate electrode connected to a first clock signal line through which a first clock signal is to be transmitted, a first electrode connected to a start signal line or an output terminal of an preceding stage of the emission control signal generator, and a second electrode connected to the second node.

6. The display device of claim 1, wherein the node control transistor comprises:
a 2-1th control transistor having a gate electrode connected to a second clock signal line through which a second clock signal is to be transmitted, a first electrode connected to a start signal line or an output terminal of an preceding stage of the emission control signal generator, and a second electrode connected to the second node; and
a 2-2th control transistor having a gate electrode connected to a first clock signal line through which a first clock signal is to be transmitted, a first electrode connected to the start signal line or the output terminal of the preceding stage of the emission control signal generator, and a second electrode connected to the second node.

7. The display device of claim 6, wherein the second clock signal has a low voltage based on a second gate low voltage lower than a gate low voltage corresponding to a low voltage of the first clock signal.

8. A display device comprising:
a display panel configured to display an image; and
a gate driver having a scan signal generator configured to supply a scan signal to the display panel, and an emission control signal generator configured to supply an emission control signal to the display panel,
wherein the emission control signal generator comprises:
a first output transistor configured to be turned on based on a first voltage charged at a first node to output an emission control signal at a turn-on voltage;
a second output transistor configured to be turned on based on a second voltage charged at the first node and different from the first voltage to output an emission control signal at a turn-off voltage;
a 1-1th control transistor configured to be turned on based on a third voltage charged at a second node to control the first voltage to be charged at the first node;
a 1-2th control transistor configured to be turned on based on a fourth voltage charged at the second node and different from the third voltage to control the second voltage to be charged at the first node; and
a node control transistor configured to transmit a signal for forming the third voltage or the fourth voltage to the second node.

9. The display device of claim 8, wherein the first output transistor has a gate electrode connected to the first node, a first electrode connected to a gate low voltage line, and a second electrode connected to an output terminal of the emission control signal generator, and the second output transistor has a gate electrode connected to the first node, a first electrode connected to a gate high voltage line, and a second electrode connected to the output terminal of the emission control signal generator.

10. The display device of claim 8, wherein the node control transistor comprises a gate electrode connected to a first clock signal line through which a first clock signal is to be transmitted, a first electrode connected to a start signal line or an output terminal of an preceding stage of the emission control signal generator, and a second electrode connected to the second node.

11. The display device of claim 8, wherein the node control transistor comprises:
a 2-1th control transistor having a gate electrode connected to a second clock signal line through which a second clock signal is to be transmitted, a first electrode connected to a start signal line or an output terminal of an preceding stage of the emission control signal generator, and a second electrode connected to the second node; and
a 2-2th control transistor having a gate electrode connected to a first clock signal line through which a first clock signal is to be transmitted, a first electrode connected to the start signal line or the output terminal of the preceding stage of the emission control signal generator, and a second electrode connected to the second node.

12. The display device of claim 8, wherein the emission control signal generator is disposed symmetrically in a non-active area on one side of the display panel and a non-active area on another side of the display panel.

13. The display device of claim 8, wherein the scan signal generator comprises:
a first scan signal generator disposed in a non-active area on one side of the display panel; and
a second scan signal generator disposed in a non-active area on another side of the display panel.

14. A gate driving circuit having an emission control signal generator, the emission control signal generator comprising:
a first output transistor configured to be turned on based on a first voltage charged at a first node to output an emission control signal at a turn-on voltage;
a second output transistor configured to be turned on based on a second voltage charged at the first node and different from the first voltage to output an emission control signal at a turn-off voltage;
a 1-1th control transistor configured to be turned on based on a third voltage charged at a second node to control the first voltage to be charged at the first node;
a 1-2th control transistor configured to be turned on based on a fourth voltage charged at the second node and different from the third voltage to control the second voltage to be charged at the first node; and
a node control transistor configured to be turned on based on at least one clock signal to transmit a signal for forming the third voltage or the fourth voltage to the second node.

15. The gate driving circuit of claim 14, wherein the clock signal is generated based on a gate high voltage corresponding to the turn-off voltage and a second gate low voltage lower than a gate low voltage corresponding to the turn-on voltage and is toggled between a high voltage and a low voltage.

16. The gate driving circuit of claim 14, wherein the node control transistor comprises a gate electrode connected to a first clock signal line through which a first clock signal is to be transmitted, a first electrode connected to a start signal line or an output terminal of an preceding stage of the emission control signal generator, and a second electrode connected to the second node.

17. The gate driving circuit of claim 14, wherein the node control transistor comprises:
a 2-1th control transistor having a gate electrode connected to a second clock signal line through which a second clock signal is transmitted, a first electrode connected to a start signal line or an output terminal of an preceding stage of the emission control signal generator, and a second electrode connected to the second node; and
a 2-2th control transistor having a gate electrode connected to a first clock signal line through which a first clock signal is transmitted, a first electrode connected to the start signal line or the output terminal of the preceding stage of the emission control signal generator, and a second electrode connected to the second node.

18. The gate driving circuit of claim 17, wherein the second clock signal has a low voltage based on a second gate low voltage lower than a gate low voltage corresponding to a low voltage of the first clock signal.
